(19) United States
(12) Patent Application Publication
(10) Pub. No.: US 2010/0002370 A1
(43) Pub. Date: Jan. 7, 2010

(54) Digital video recorder with an ejector frame assembly

(76) Inventor: Yi-Jen Cheng, Taichung (TW)

Correspondence Address: Frenkel & Associates, P.C., Suite 330, 3975 University Drive, Fairfax, VA, 22030, US

(21) Appl. No.: 12/217,156

(22) Filed: Jul. 2, 2008

(51) Int. Cl. H05K 7/18

(52) U.S. Cl. 361/679.38

(57) ABSTRACT

A digital video recorder with an ejector frame assembly has a body, at least one hard disk, a front panel and an ejector frame. The body has a case and a cover. The case has a top surface, a bottom inner surface and an opening. The opening is formed through the top surface of the case. The cover selectively covers the opening. The ejector frame mounts the hard disk, is raiseably mounted on the bottom inner surface and is disposed facing to the opening. A person may slide the cover and lift the ejector frame to remove the hard disk easily.

### BACKGROUND OF THE INVENTION

1. Field of Invention

The present invention relates to a digital video recorder (DVR), and more particularly to a DVR having an internal hard disk that is detachably mounted on a fast-detaching assembly, wherein the internal hard disk can be easily removed from the fast-detaching assembly of the DVR.

2. Description of the Related Art

Video cassette recorders (VCRs) are rapidly diminishing and are being replaced by Digital Video recorders (DVRs) with an embedded hard disk. DVRs with an internal hard disk are widely used for receiving audio-video signals from video cameras, video monitors, television cable and the like.

However, the internal hard disk may need to be removed from the DVR for maintenance, data transmission and replacement with another hard disk. Unfortunately, removal of the internal hard disk from a conventional DVR is troublesome because a person needs to remove many screws to remove a cover of the DVR before removing the internal hard disk, which dissuades people from investing in this technology.

To prevent the disadvantages described above, some hard disk detachable DVRs are provided. Hard disks inside the hard disk detachable DVRs are normally mounted on a drawer or a movable brace so that the hard disks are easily removed from bodies of the hard disk detachable DVRs with pulling or lifting the drawer or the movable brace.

However, the hard disks are at risk of being damaged when the drawer or movable brace are moved from the body of the hard disk detachable DVRs since either the drawer or the movable brace has no movement protection elements for holding the drawer or the movable brace in after detached from the body.

The present invention provides a digital video recorder with an ejector frame assembly to obviate or mitigate the shortcomings of the conventional DVR.

### SUMMARY OF THE INVENTION

The primary objective of the present invention is to provide a digital video recorder (DVR) with a fast detaching hard disk assembly that is allows safe and easy replacement, removal or maintenance access to the hard disk.

The digital video recorder with an ejector frame assembly has body, at least one hard disk, a front panel and an ejector frame. The body has a case and a cover. The case has a top surface, a bottom inner surface and an opening. The opening is formed through the top surface of the case. The cover selectively covers the opening. The ejector frame mounts the hard disk, is raiseably mounted on the bottom inner surface and is disposed facing to the opening. A person may slide the cover and lift the ejector frame to remove the hard disk easily.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a digital video recorder (DVR) with an ejector frame assembly in accordance of the present invention;

FIG. 2 is an operational perspective view of the DVR with an ejector frame assembly in FIG. 1;

FIG. 3 is a partially exploded perspective view of the DVR with an ejector frame assembly in FIG. 1;

FIG. 4A is a side view in partial section of the DVR with an ejector frame assembly in FIG. 1, showing the ejector frame assembly retracted inside a case;

FIG. 4B is a side view in partial section of the DVR with an ejector frame assembly in FIG. 1, showing the ejector frame assembly extended outside the case; and

FIG. 5 is an enlarged, partially exploded perspective view of the DVR with an ejector frame assembly in FIG. 1.

### DETAILED DESCRIPTION OF THE INVENTION

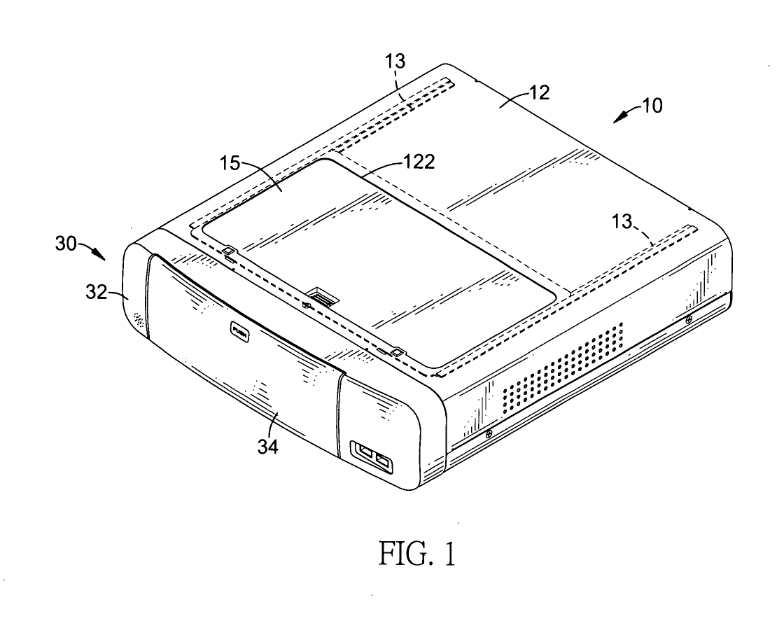

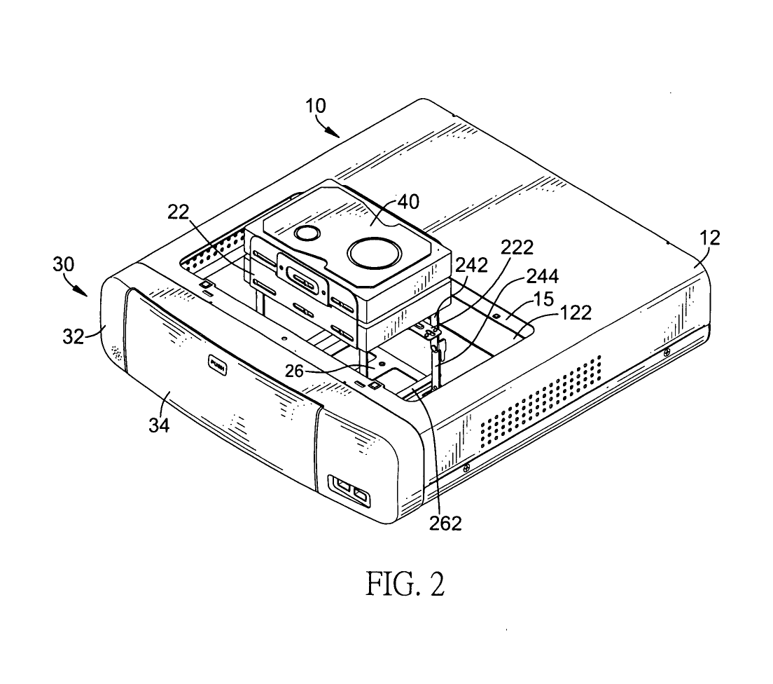

With reference to FIGS. 1 and 2, a digital video recorder (DVR) with an ejector frame assembly in accordance with the present invention comprises a body (10), at least one hard disk (40), a front panel (30) and an ejector frame assembly (20).

The body (10) is a DVR and may have a circuit module that is capable of connecting external audio-video (AV) devices and receiving signals from the AV devices to records the signals in a storage device inside the DVR. The body (10) has a case (12), two optional sliding rails (13) and a cover (15).

The case (12) may be a parallelepiped comprising a front end, a top surface and a bottom inner surface.

The top surface of the case (12) has an opening (122) being formed through the top surface, being larger than and may further be shaped to correspond to a hard disk.

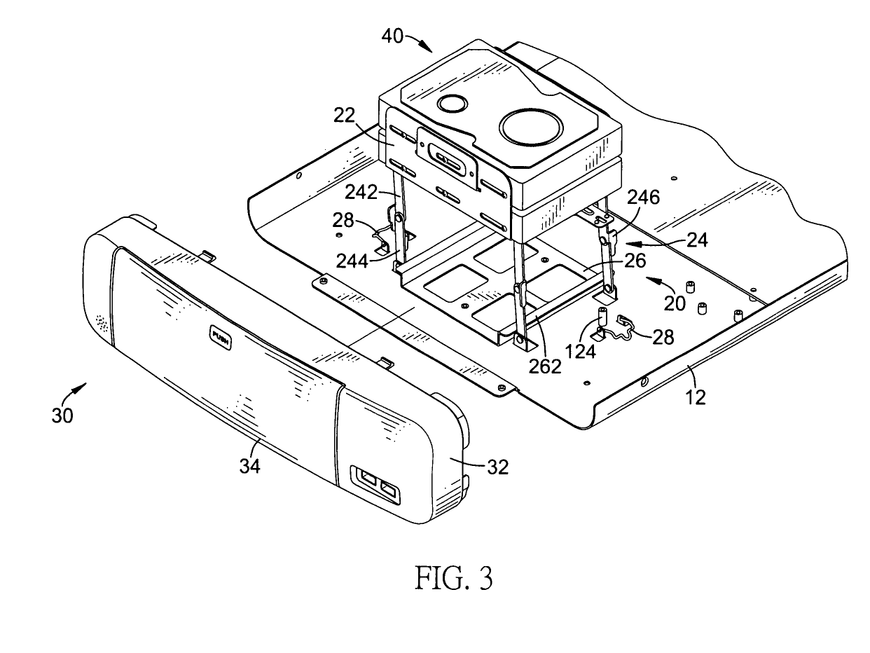

With further reference to FIG. 3, the bottom inner surface faces the top surface of the case (12) and may have at least one stage mount (124).

The at least one stage mount (124) protrudes from the bottom inner surface of the case (12) and may be disposed facing to an edge of the opening (122).

The sliding rails (13) are parallelly and separately mounted on the top surface of the case (12) adjacent to the opening (122).

The cover (15) corresponds to and removably covers the opening (122). The cover (15) may be slidably mounted on the sliding rails (13) or may be hinged on the top surface to selectively cover the opening (122).

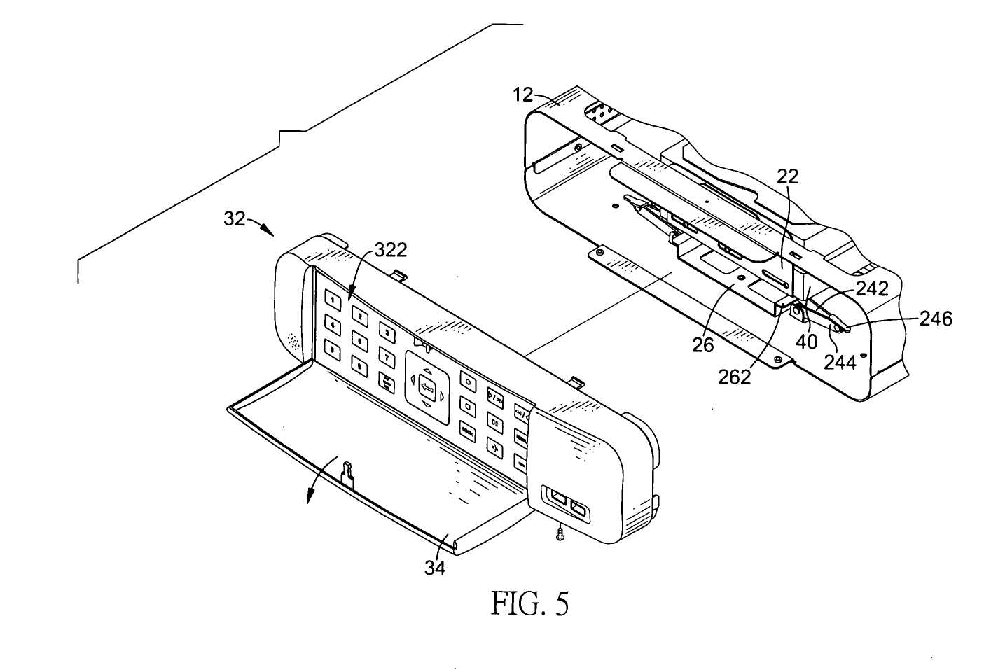

With further reference to FIG. 5, the front panel (30) is an electrical control panel of the DVR, is mounted on the front end of the case (12) and has a panel body (32) and a panel cover (34).

The panel body (32) is mounted on the front end of the case (12) and has a functional button set (322). The functional button set (322) may be switches, film electric buttons, a touch screen panel or the like and are used for operating the DVR for functions such as but not limited to toggling power setting, fast winding, stop, play and so on and may further comprise an infrared sensor for remote control.

The panel cover (34) is pivotally mounted on the panel body (32) corresponding to the functional button set (322) and selectively covers and uncovers the functional button set (322).

The ejector frame assembly (20) is mounted raiseably on the bottom inner surface and is disposed corresponding to the opening (122) and has a hard disk housing (22), multiple extendable legs (24), a positionor (26) and at least one fastener (28).

The hard disk housing (22) corresponds to and removably mounts the hard disk (40) thereon, is smaller than the opening (122), has a bottom panel and may have at least one fastening tab (222). The bottom panel of the hard disk housing (22) may be a rectangular plate having four corners corresponding to the hard disk (40).

The at least one fastening tab (222) is formed on and extends from the bottom panel of the hard disk housing (22) and the at least one fastening tab (222) corresponds to a stage mount (124).

The extendable legs (24) are separately mounted between the hard disk housing (22) and the bottom inner surface of the case (12). Each one of the extendable legs (24) may be a telescopic rod or a hinged rod and has two ends.

In a preferred embodiment of the present invention, four extendable legs (24) are separately mounted between the hard disk housing (22) and the bottom inner surface of the case (12) and are respectively mounted on four corners of the bottom panel. The ends of each extendable leg (24) are pivotally mounted respectively on the hard disk housing (22) and the bottom inner surface of the case (12). Each extendable leg (24) has a top rod (242), a bottom rod (244) and a limit tab (246).

The top rod (242) and the bottom rod (244) are pivotally mounted to each other and are respectively mounted pivotally on the hard disk housing (22) and the bottom inner surface of the case (12).

The limit tab (246) is formed on the top rod (242), extends from the top rod (242) to the bottom rod (244) and prevents the top rod (242) and the bottom rod (244) bending incorrectly.

The positionor (26) is mounted on the bottom inner surface of the case (12) adjacent to the extendable legs (24), providing support to, may by preventing over-rotation of, the extendable legs (24) when fully extended, may be a bent sheet or a rectangular plate being disposed between and surrounded by the extendable legs (24), and may be a rectangular frame mounted surrounding the extendable legs (24) and has two positioning edges (262).

The positioning edges (262) are parallel to each other, each one of the positioning edges (262) selectively abuts the bottom rods (244) of two of the extendable legs (24) when the extendable legs (24) are fully extended.

In the preferred embodiment of the present invention, the positionor (26) is a bent sheet having two parallel bent edges respectively forming the two positioning edges (262). Each positioning edge (262) is disposed adjacent to two extendable legs (24) and abuts the bottom rod (244) when the extendable legs (24) are extended.

The at least one fastener (28) is pivotally mounted on the bottom inner surface of the case (12). The at least one fastener (28) is disposed adjacent to a corresponding stage mount (124) and selectively clamps a corresponding fastening tab (222) to the stage mount (124) to lock the hard disk housing (22) on the stage mount (124).

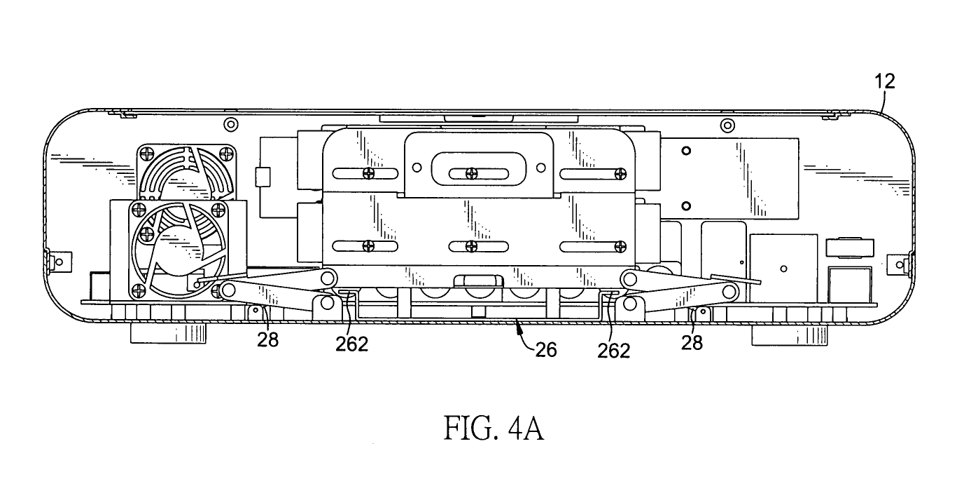

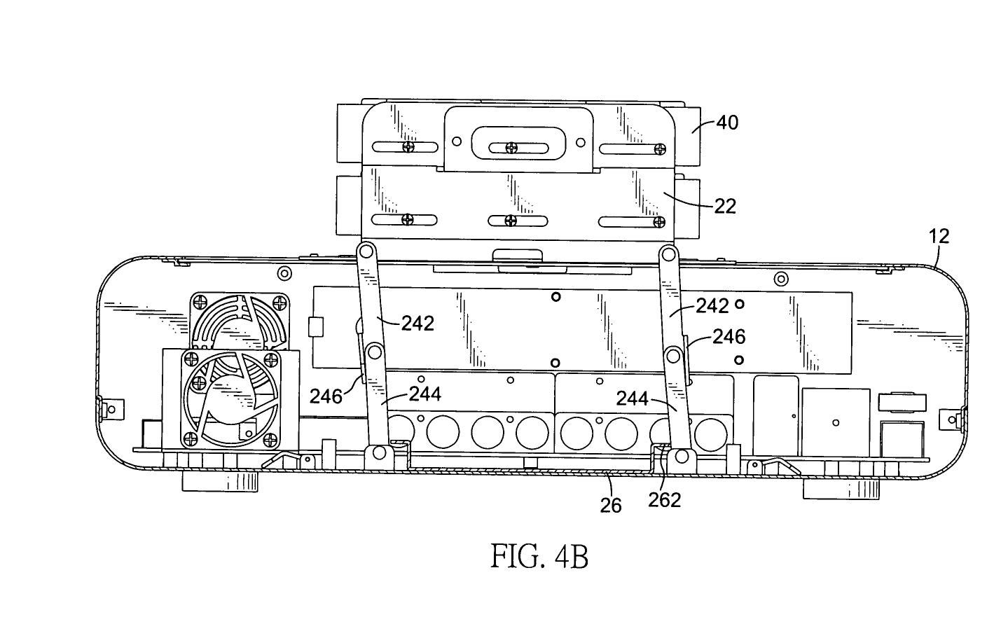

With reference to FIGS. 4A and 4B, a person may easily remove the hard disk (40) from the case (12) by sliding the cover (15) along the sliding rails (13), unclamping the fastener (28), lifting up the hard disk housing (22) until the extendable legs (24) are fully extended; and removing the hard disk (40) from the hard disk housing (22).

When extended, the hard disk housing (22) will be supported by the extendable legs (24) at a fixed position after the extendable legs (24) are fully extended since the extendable legs (24) are limited by the positioning edges (262) and the limit tabs (246). Therefore, the hard disk (40) can be safety mounted or removed from the hard disk housing (22) simply and efficiently.

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A digital video recorder (DVR) comprising
a body being a DVR and having
a case having
a front end;
a top surface having an opening being formed through the top surface; and
a bottom inner surface; and
a cover being shaped corresponding to and removably covering the opening;
at least one hard disk;
a front panel being an electrical control panel of the DVR and being mounted on the front end of the case; and
an ejector frame assembly being mounted raiseably on the bottom inner surface and being disposed corresponding to the opening and having
a hard disk housing corresponding to and removably mounting the at least one hard disk thereon and being smaller than the opening;
multiple extendable legs being separately mounted between the hard disk housing and the bottom inner surface of the case and each one of the extendable legs having two ends being mounted respectively on the hard disk housing and the bottom inner surface of the case; and
a positionor being mounted on the bottom inner surface of the case adjacent to the extendable legs, providing support to the extendable legs.

2. The DVR as claimed in claim 1, wherein
the hard disk housing has a bottom panel being a rectangular plate having four corners;
the ejector frame assembly has four extendable legs being separately mounted between hard disk housing and the bottom inner surface of the case, being respectively and pivotally mounted on the hard disk housing and being mounted to the four corners of the bottom panel of the hard disk housing, each extendable leg having
a top rod being pivotally mounted on the hard disk housing;
a bottom rod being serially and pivotally mounted on the top rod and being pivotally mounted on the bottom inner surface of the case; and
a limit tab being formed on the top rod, extending from the top rod to the bottom rod and preventing the top rod and the bottom bending incorrectly; and
the positionor is a bent sheet being mounted on the bottom surface adjacent to the extendable legs and has
two positioning edges, the positioning edges being parallel to each other and each one of the positioning edges selectively abutting the bottom rods of two of the extendable legs when the extendable legs being fully extended.

3. The DVR with an ejector frame assembly as claimed in claim 1, wherein the case has two sliding rails being parallelly and separately mounted on the top surface of the case adjacent to the opening; and
the cover is mounted slidably on the sliding rails.

4. The DVR with an ejector frame assembly as claimed in claim 2, wherein the case has two sliding rails being parallelly and separately mounted on the top surface of the case adjacent to the opening; and
the cover is mounted slidably on the sliding rails.

5. The DVR with an ejector frame assembly as claimed in claim 3, wherein
the case has at least one stage mount protruding from the bottom inner surface of the case and being disposed facing an edge of the opening;
the hard disk housing has at least one fastening tab being formed on and extending from the bottom panel of the hard disk housing and the at least one fastening tab corresponding respectively to the at least one stage mount; and
the ejector frame assembly has at least on fastener being pivotally mounted on the bottom inner surface of the case, each one of the at least one fastener being disposed adjacent to one stage mount and selectively clamping one fastening tab onto a corresponding the stage mount.

6. The DVR with an ejector frame assembly as claimed in claim 4, wherein
the case has at least one stage mounts protruding from the bottom inner surface of the case and being disposed facing an edge of the opening;
the hard disk housing has at least one fastening tab being formed on and extending from the bottom panel of the hard disk housing and the at least one fastening tab corresponding respectively to the at least one stage mount; and
the ejector frame assembly has at least on fastener being pivotally mounted on the bottom inner surface of the case, each one of the at least one fastener being disposed adjacent to one stage mount and selectively clamping one fastening tab onto a corresponding the stage mount.

7. The DVR with an ejector frame assembly as claimed in claim 5, wherein the front panel further has
a panel body being mounted on the front end of the case and having a functional button set; and
a panel cover being pivotally mounted on the panel body corresponding to the functional button set and selectively covering the functional button set.

8. The DVR with an ejector frame assembly as claimed in claim 6, wherein the front panel further has
a panel body being mounted on the front end of the case and having a functional button set; and
a panel cover being pivotally mounted on the panel body corresponding to the functional button set and selectively covering the functional button set.
